(19) United States
(12) Patent Application Publication
(10) Pub. No.: US 2026/0047108 A1
(43) Pub. Date: Feb. 12, 2026

(54) LIGHT SENSING AND MEMORY INTEGRATED ELECTRONIC DEVICE GENERATING ELECTRICAL SPIKE

(71) Applicant: National Cheng Kung University, Tainan City (TW)

(72) Inventors: Jen-Sue CHEN, Tainan City (TW); Kuan-Ting CHEN, Tainan City (TW); Pei-Lin LIN, Tainan City (TW); Shuai-Ming CHEN, Tainan City (TW)

(73) Assignee: National Cheng Kung University, Tainan City (TW)

(21) Appl. No.: 18/909,283

(22) Filed: Oct. 8, 2024

(30) Foreign Application Priority Data
Aug. 6, 2024 (TW) 113129467

(51) Int. Cl. H10B 99/00; H01L 31/032; H01L 31/113

(52) U.S. Cl. CPC H10B 99/14; H10F 30/282; H10F 77/12

(57) ABSTRACT

A light sensing and memory integrated electronic device includes a thin film transistor element and a memory element. The thin film transistor element includes a channel layer, a source layer and a drain layer. The channel layer is made of a transparent oxide. The memory element is on the source layer. The memory element includes a lower metal layer, a dielectric layer, a matching metal layer, and an upper metal layer stacked in sequence from bottom to top, where the lower metal layer is connected to the source layer. The light sensing and memory integrated electronic device provides a single device to perform light sensing, memorizing, and generating a spike-form signal required by a neural network. It can simplify a circuit and effectively reduce the photoelectric signal conversion time, and it can also make it more lightweight and improve space utilization efficiency, and achieve higher computing power.

### CROSS-REFERENCE TO RELATED APPLICATION

This non-provisional application claims priority under 35 U.S.C. § 119(a) to Patent Application No. 113129467 filed in Taiwan, R.O.C. on Aug. 6, 2024, the entire contents of which are hereby incorporated by reference.

### BACKGROUND

### Technical Field

The present disclosure relates to the field of electronic devices, and in particular to a light sensing and memory integrated electronic device.

### Related Art

Artificial intelligence (AI) technology is undoubtedly the biggest promoter of the next generation of industrial technology, which, with a wide range of applications and a potential to dramatically change the existing technology ecosystem, will lead to the emergence of a new wave of high-performance computing demands.

Actually, artificial intelligence has been developed for many years, in which neuromorphic computing is a computing architecture that scientists seek to break through traditional chips. Inspired by the massively parallel computing with ultra-low power consumption of a human brain, its design structure forms a huge neural circuit including neurons and synapses, which can more effectively train and run deep learning neural networks in AI chips. Spike neural network (SNN) is a network model that most conforms to the actual operation of human brain neurons. It conveys information in the form of spikes, and achieves effects of network learning and decision-making through the transmission of spikes, thereby providing faster information processing capabilities with lower energy consumption. It is a highly anticipated architecture combining neuroscience and machine learning in recent years.

To realize SNN in hardware, an encoder that can convert signals into pulse form is required. However, traditional solid-state sensors cannot achieve this purpose, and signals received from the outside must first be processed by a number of devices such as an analog-to-digital converter and a frequency converter before pulses are generated. At present, a typical method is to use complementary metal oxide semiconductors (CMOSs) as the synapse and neuron mimicking architecture. Usually, four CMOSs and two comparators are needed in one synapse mimicking unit, and two comparators, one phase change controller and one pulse encoder are needed in one neuron mimicking unit. Due to the complexity of the circuit and elements, the overall power consumption and cost are very high.

In contrast to two-terminal memory devices proposed previously for synaptic and neuronal functions, our transistor-memory series circuit modulates conductance (synaptic weight) using optical and gate bias stimulation. This approach reduces the risk of unintended weight changes caused by voltage division between serial components during operation.

### SUMMARY

In order to reduce the time difference between sensing and pulse compilation and the circuit complexity, the present disclosure provides a light sensing and memory integrated electronic device, including a thin film transistor element and a memory element. The thin film transistor element includes a channel layer, a source layer and a drain layer. The channel layer is made of a transparent oxide. The source layer and the drain layer are arranged on the channel layer separately from each other. The memory element is arranged on the source layer. The memory element includes a lower metal layer, a dielectric layer, a matching metal layer and an upper metal layer stacked in sequence from bottom to top. The lower metal layer is connected to the source layer.

In some examples, the transparent oxide is selected from the group consisting of zinc oxide, indium oxide, gallium oxide, zinc tin oxide, indium zinc oxide (IZO), indium gallium oxide and indium gallium zinc oxide (IGZO).

In some examples, the source layer and the drain layer are made of aluminum.

In some examples, the drain layer includes an aluminum layer and a platinum layer. The aluminum layer is in contact with the channel layer, and the platinum layer is stacked on the aluminum layer.

In some examples, the lower metal layer and the upper metal layer are made of platinum.

In some examples, the dielectric layer is selected from the group consisting of aluminum oxide, tantalum oxide, zirconium oxide, hafnium oxide, titanium oxide, tungsten oxide and niobium oxide.

In more detail, in some examples, the matching metal layer is made of vanadium (V).

In some examples, a thickness of the channel layer is about 1/12 to 1/10 of a thickness of the source layer and the drain layer.

In some examples, a thickness of the upper metal layer is ⅔ to ¾ of a thickness of the lower metal layer, a thickness of the dielectric layer is ⅖ to ⅗ of the thickness of the lower metal layer, a thickness of the matching metal layer is 9/8 to 5/4 of the thickness of the lower metal layer, and the thickness of the lower metal layer is ⅖ to ⅗ of the thickness of the source layer and the drain layer.

In some examples, the light sensing and memory integrated electronic device further includes a base. The thin film transistor element is located on the base, the base includes a P-doped silicon substrate and a silicon dioxide layer, and the silicon dioxide layer is located between the P-doped silicon substrate and the channel layer.

Based on the above, the present disclosure provides the light sensing and memory integrated electronic device. The light sensing and memory integrated electronic device provides a single device, which can perform effects of light sensing and volatile memory and can convert a current signal into a spike form through modulation of applied voltage so as to perform encoding and discrimination. On the premise of reducing circuit elements, the light sensing and memory integrated electronic device can simplify a circuit and effectively reduce the photoelectric signal conversion time, and it can also make it more lightweight and improve space utilization efficiency, and achieve higher computing power.

### BRIEF DESCRIPTION OF THE DRAWINGS

FIG. 1 is a schematic three-dimensional diagram of a light sensing and memory integrated electronic device according to an example;

FIG. 2 is a schematic sectional diagram of a light sensing and memory integrated electronic device according to another example;

FIG. 3A is a schematic operation diagram of the light sensing and memory integrated electronic device;

FIG. 3B is an equivalent circuit diagram of the light sensing and memory integrated electronic device;

FIG. 3C is an I-V curve graph of the light sensing and memory integrated electronic device;

FIG. 4 is an I-t curve graph of the light sensing and memory integrated electronic device at a variable number of input light waves under irradiation;

FIG. 5A is an I-V curve graph of the light sensing and memory integrated electronic device at a variable irradiation-gate voltage;

FIG. 5B is an I-t curve graph of the light sensing and memory integrated electronic device at a variable irradiation intensity;

FIG. 6 is an I-t curve graph of the light sensing and memory integrated electronic device at a variable irradiation intensity and a constant voltage according to an experimental example;

FIG. 7 is an I-t spike encoding pattern of the light sensing and memory integrated electronic device at voltage square waves after irradiation according an experimental example;

FIG. 8 is an I-t spike encoding pattern at constant voltage square waves after irradiation; and

FIG. 9A to FIG. 9E are I-t graphs of spike signal encoding at a variable voltage.

### DETAILED DESCRIPTION

In the following description, the terms “first”, “second” and “third” are merely used to distinguish one element, component, area, layer or part from another element, component, area, layer or part, and do not indicate their necessary order. Besides, relative terms such as “lower” and “upper”, and “inner” and “outer” may be used herein to describe the relationship of one element to another, and it should be understood that relative terms are intended to include different orientations of the apparatus other than those shown in the drawings. For example, if the apparatus in one drawing is turned over, the element described as being on the “lower” side of the other element will be oriented on the “upper” side of the other element. This only indicates the relative orientation relationship, not the absolute orientation relationship.

In the drawings, the widths of some elements, areas, etc. are enlarged for clarity. Throughout this specification, similar reference numerals refer to similar elements. It should be understood that when, for example, an element is defined as being “on” or “connected to” another element, it may be directly on or connected to another element, or there may also be an intermediate element. On the contrary, when an element is defined to be “directly on” or “directly connected to” another element, there is no intermediate element.

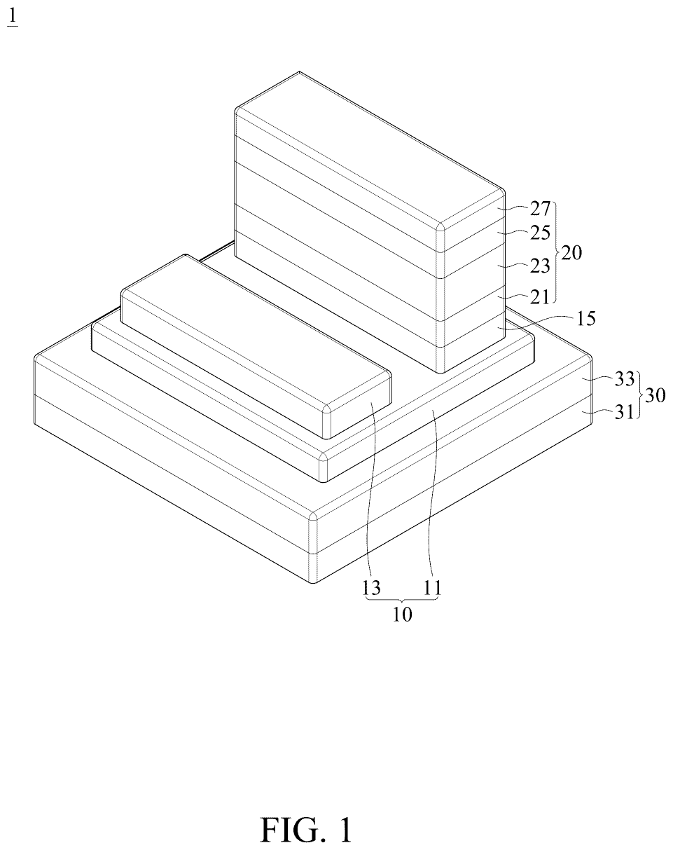

FIG. 1 is a schematic three-dimensional diagram of a light sensing and memory integrated electronic device according to an example. As shown in FIG. 1, the light sensing and memory integrated electronic device 1 includes a thin film transistor element 10 and a memory element 20. The thin film transistor element 10 includes a channel layer 11, a drain layer 13 and a source layer 15. The channel layer 11 is made of a transparent oxide. The drain layer 13 and the source layer 15 are arranged on the channel layer 11 separately from each other. The memory element 20 is arranged on the source layer 15. The memory element 20 includes a lower metal layer 21, a dielectric layer 23, a matching metal layer 25 and an upper metal layer 27 stacked in sequence from bottom to top. The lower metal layer 21 is connected to the source layer 15.

In some examples, the transparent oxide may be at least one of zinc oxide, indium oxide, gallium oxide, indium zinc oxide (IZO), indium gallium oxide or indium gallium zinc oxide (IGZO).

In some examples, the drain layer 13 and the source layer 15 are made of aluminum. Further, in some examples, the dielectric layer 23 may be made of at least one of aluminum oxide, tantalum oxide, zirconium oxide, hafnium oxide, titanium oxide, tungsten oxide or niobium oxide.

In some examples, the lower metal layer 21 and the upper metal layer 27 are made of platinum. In more detail, in some examples, the matching metal layer 25 is made of vanadium (V).

In some examples, a thickness of the channel layer 11 is about 1/12 to 1/10 of a thickness of the drain layer 13 and the source layer 15. Further, in some examples, a thickness of the upper metal layer 27 is ⅔ to ¾ of a thickness of the lower metal layer 21, a thickness of the dielectric layer 23 is ⅖ to ⅗ of the thickness of the lower metal layer 21, a thickness of the matching metal layer 25 is 9/8 to 5/4 of the thickness of the lower metal layer 21, and the thickness of the lower metal layer 21 is ⅖ to ⅗ of the thickness of the drain layer 13 and the source layer 15.

For example, the thickness of the channel layer 11 currently fabricated with laboratory equipment is 5 nm to 14 nm, the thickness of the drain layer 13 and the source layer 15 is 90 nm to 120 nm, the thickness of the lower metal layer 21 is 45 nm to 60 nm, the thickness of the dielectric layer 23 is 18 nm to 35 nm, the thickness of the matching metal layer 25 is 55 nm to 68 nm, and the thickness of the upper metal layer 27 is 30 nm to 45 nm. However, the above is merely an example, and is not intended to be limiting. In the manufacturing process of a wafer factory, the actual sizes can be further scaled according to the above proportion.

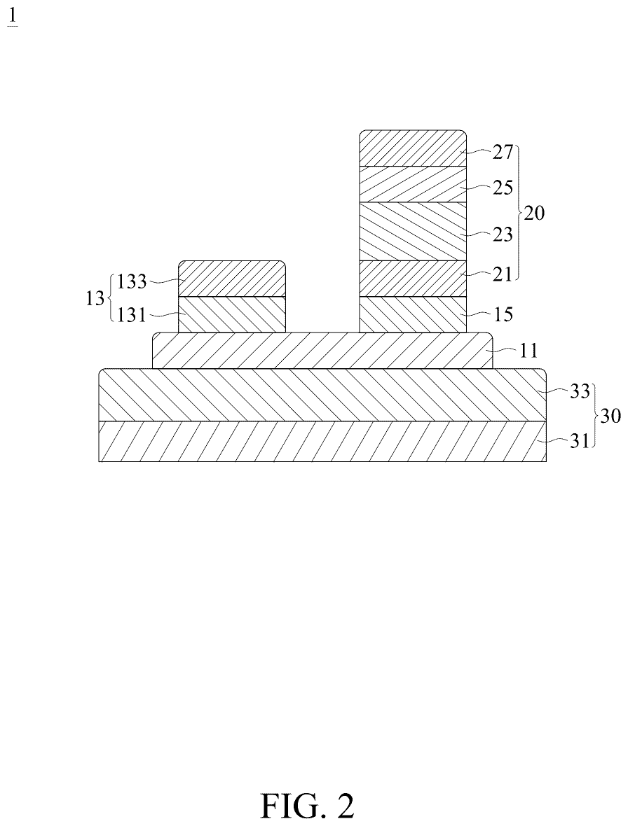

FIG. 2 is a schematic sectional diagram of a light sensing and memory integrated electronic device according to another example. In some examples, the drain layer 13 includes an aluminum layer 131 and a platinum layer 133. The aluminum layer 131 is in contact with the channel layer 11, the platinum layer 133 is stacked on the aluminum layer 131, and the source layer 15 is made of aluminum.

Still referring to FIG. 1 and FIG. 2, in some examples, the light sensing and memory integrated electronic device 1 further includes a base 30. The thin film transistor element 10 is located on the base 30. The base 30 includes a P-doped silicon substrate 31 and a silicon dioxide layer 33. The silicon dioxide layer 33 is located between the P-doped silicon substrate 31 and the channel layer 11. A thickness of the P-doped silicon substrate 31 is greater than a thickness of the silicon dioxide layer 33. For example, the thickness of the P-doped silicon substrate 31 is about 500 μm, and the thickness of the silicon dioxide layer 33 is about 100 nm.

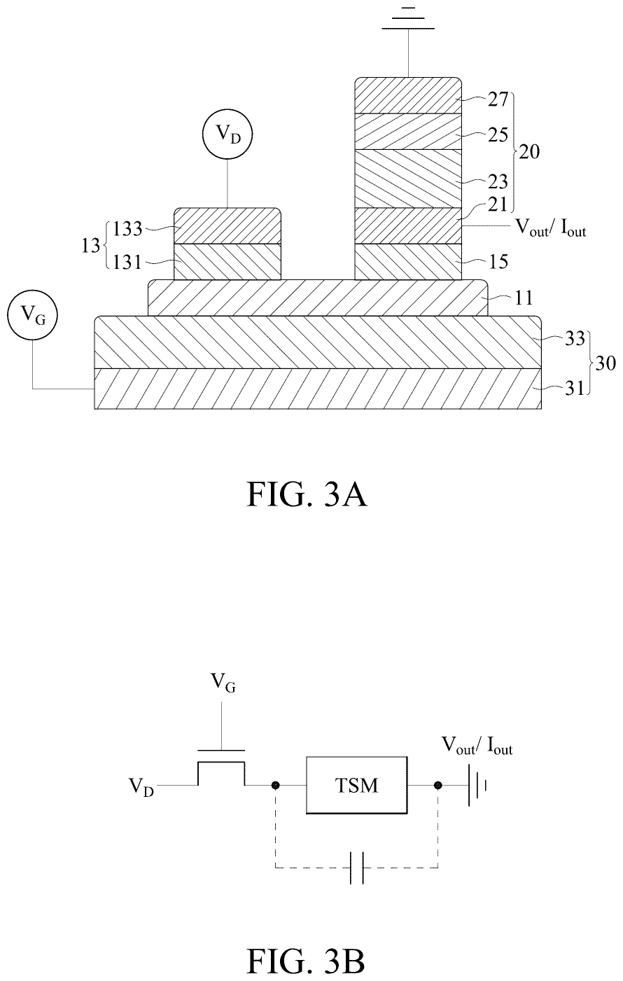

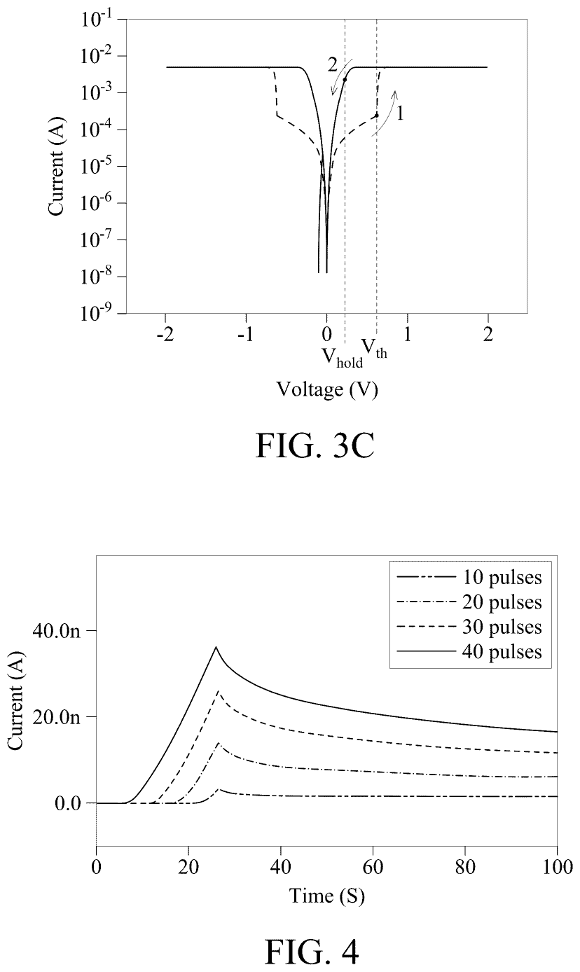

FIG. 3A is a schematic operation diagram of the light sensing and memory integrated electronic device. FIG. 3B is an equivalent circuit diagram of the light sensing and memory integrated electronic device. FIG. 3C is an I-V curve graph of the light sensing and memory integrated electronic device. The following experiments are conducted based on the example of FIG. 2, in which the thickness of the P-doped silicon substrate 31 is about 500 μm, the thickness of the silicon dioxide layer 33 is about 98 nm, and the channel layer 11 is indium gallium zinc oxide (IGZO) having a thickness of 10 nm. The thickness of the aluminum layer 131 of the drain layer 13 is 104 nm, and the thickness of the platinum layer 133 is 54 nm. The source layer 15 is made of aluminum having a thickness of 104 nm. The lower metal layer 21 is made of platinum having a thickness of 54 nm, the dielectric layer 23 is made of aluminum oxide having a thickness of 27 nm, the matching metal layer 25 is made of vanadium having a thickness of 64 nm, and the upper metal layer 27 is made of platinum having a thickness of 37 nm. The above data only present experimental examples, are not intended to be limiting. It should be noted here that FIG. 1, FIG. 2 and FIG. 3A are not drawn to scale for the sake of clarity.

As shown in FIG. 3A to FIG. 3B, a gate voltage V_{G} is applied to the base 30 on gate layer 31, a drain voltage V_{D} is applied to the drain layer 13, the upper metal layer 27 is grounded, and a read voltage Vₒᵤₜ and a read current Iₒᵤₜ of the source layer 15 outputted subsequently are captured. Here, the equivalent circuit of the memory element 20 may be considered as a combination of a capacitor and a memory.

In some examples, the gate voltage V_{G} and the drain voltage V_{D} are both set to 10 V. As shown in FIG. 3C, when a charging mode is performed, as shown in curve 1 in FIG. 3C, when the voltage increases above the threshold voltage Vₜₕ, for example, 0.8 V, the current suddenly rises. In a discharging process, as shown in curve 2 in FIG. 3C, the voltage decreases until the voltages is lower than a holding voltage V_{hold}, for example, 0.2 V, the current suddenly drops. This feature provides a state of maintaining a certain capacitance, which, in the equivalent circuit, is like a parallel connection between the memory element 20 and a parasitic capacitor.

FIG. 4 is an I-t curve graph of the light sensing and memory integrated electronic device at a variable number of input light waves under irradiation. As shown in FIG. 4, in a case where the light sensing and memory integrated electronic device 1 is irradiated, the light sensing and memory integrated electronic device 1 is irradiated by pulsed laser light with a wavelength of 405 nm while the gate voltage V_{G} is set to 0 V and the drain voltage V_{D} is set to 10 V. The currents are measured at different number of pulses, and the number of pulses is 10, 20, 30 and 40. The transparent oxide of the channel layer 11 generates photocurrent after being excited by light with sufficient energy and intensity. After the irradiation, the size of the current is directly proportional to the number of pulses. Moreover, after about 30 seconds, after the light irradiation is stopped, the current tends to decrease slowly, but will not decrease to the current value before the irradiation, thereby achieving effects of light sensing and memory.

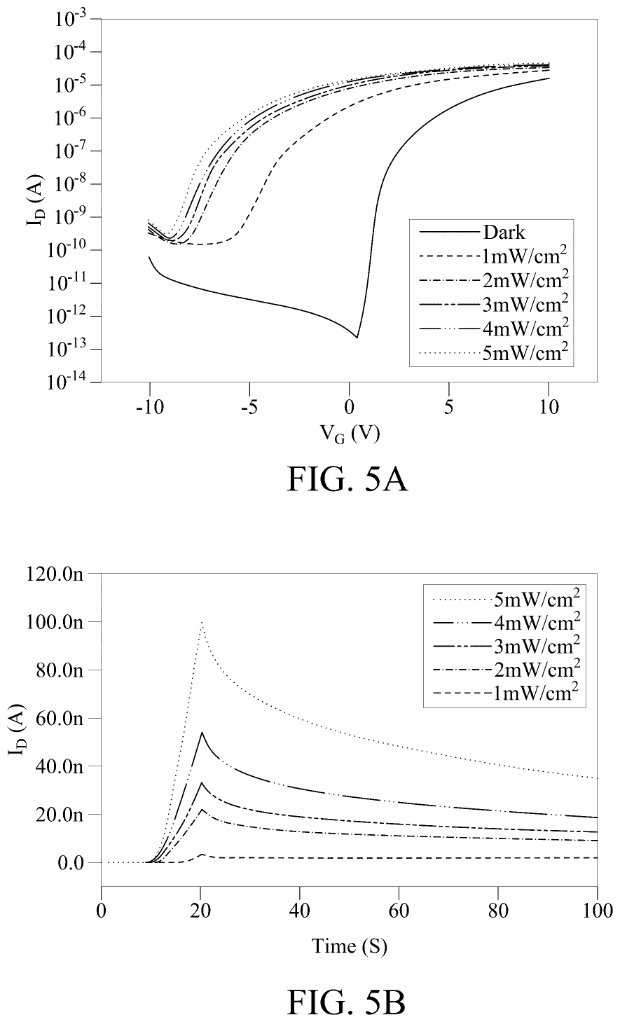

FIG. 5A is an I-V curve graph of the light sensing and memory integrated electronic device at a variable irradiation-gate voltage. FIG. 5B is an I-t curve graph of the light sensing and memory integrated electronic device at a variable irradiation intensity. FIG. 5A and FIG. 5B show I-V comparison when setting the gate voltage V_{G} from −10 V to 10 V, and when not irradiated and irradiated by 405 nm laser light with different irradiation intensities. FIG. 5B shows comparison when irradiated by laser light at a frequency of 20 pulses/10 s and with different irradiation intensities. Referring to FIG. 4, as the irradiation stimulation increases, the current also increases accordingly.

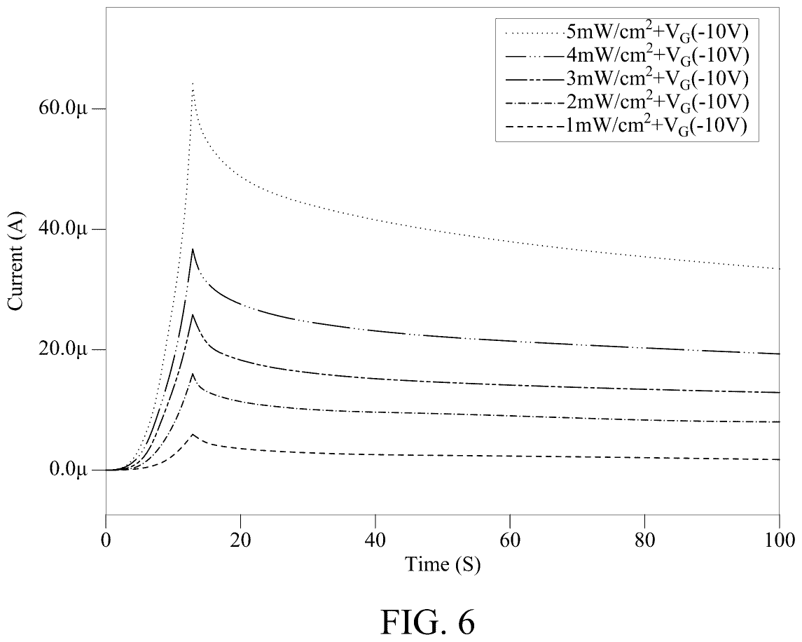

FIG. 6 is an I-t curve graph of the light sensing and memory integrated electronic device at a variable irradiation intensity and a constant voltage according to an experimental example. FIG. 6 shows current-time curves, obtained by applying voltage pulses with a gate voltage V_{G} of −10 V at the time of irradiation of the light pulse wave in synchronization with the frequency of light pulse irradiation, and recording the current at a drain voltage V_{D} of 10 V. Referring to FIG. 4 and FIG. 5a, the trends of the current curves are substantially the same.

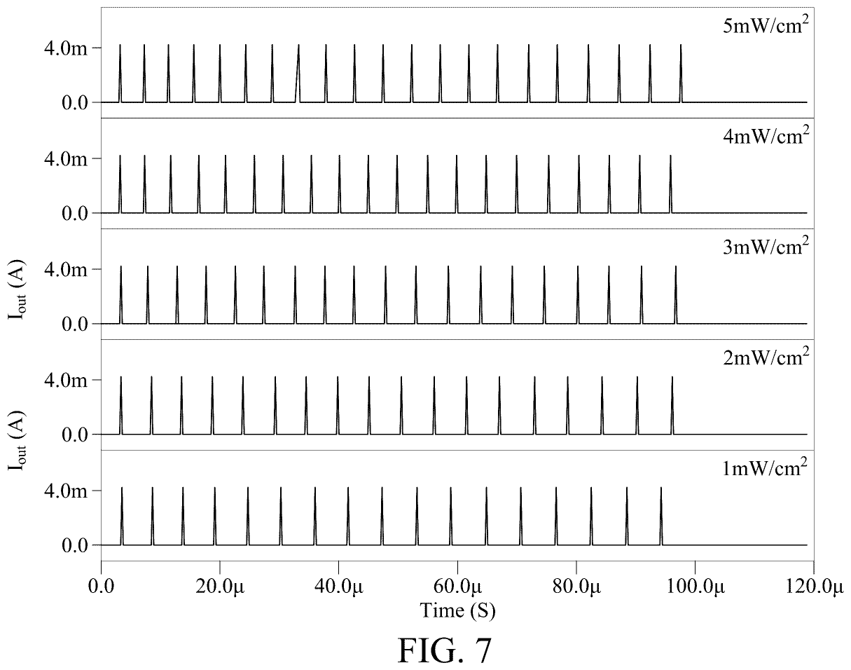

FIG. 7 is an I-t spike encoding pattern of the light sensing and memory integrated electronic device at voltage square waves after irradiation according an experimental example. In this experiment, the drain voltage V_{D} is set to 10 V. The gate voltage V_{G} is set to a 100 μs pulse voltage of 10 V. After irradiation by light with different light intensities, as can be found from the I-t curves, spikes produced under different light intensities have different intervals, which may also be used as a feature for discrimination.

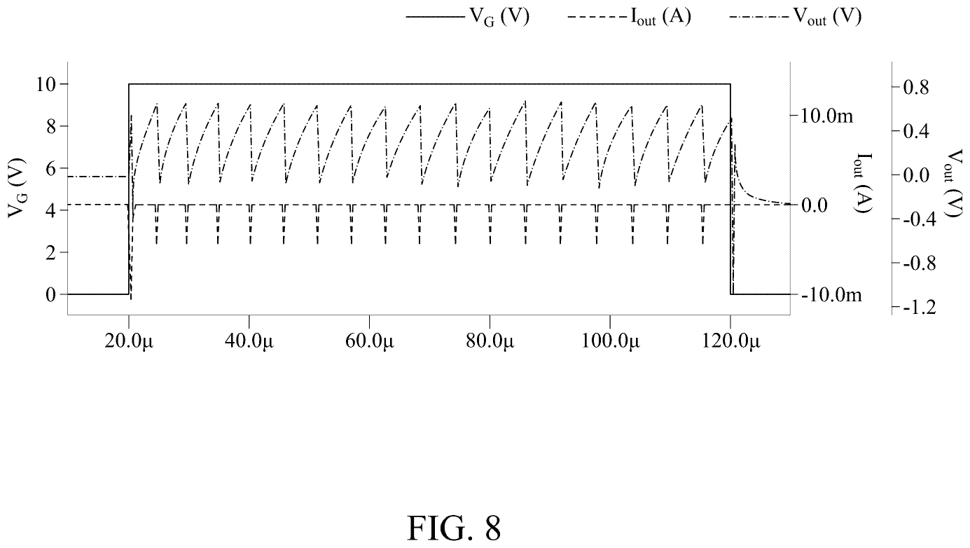

FIG. 8 is an I-t spike encoding pattern at constant voltage square waves after irradiation. As shown in FIG. 8, in FIG. 8, the irradiation intensity is set to 1 mW/cm², and the drain voltage V_{D} is set to 10 V. In this experiment, the gate voltage V_{G} is fixed at 10 V for 100 μs. During this process, it can be found that the voltage drop of the memory element 20 increases and decreases, exhibiting an oscillating line, and spike signals similar to pulses are read at the upper metal layer 27 of the memory element 20.

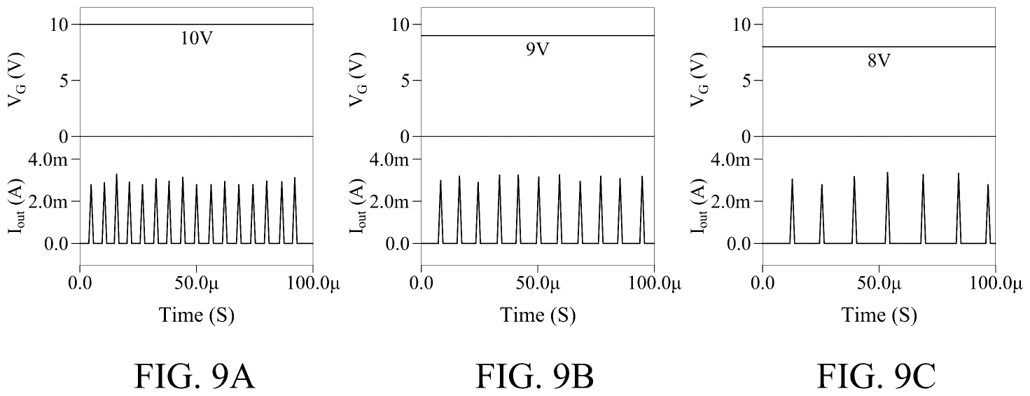

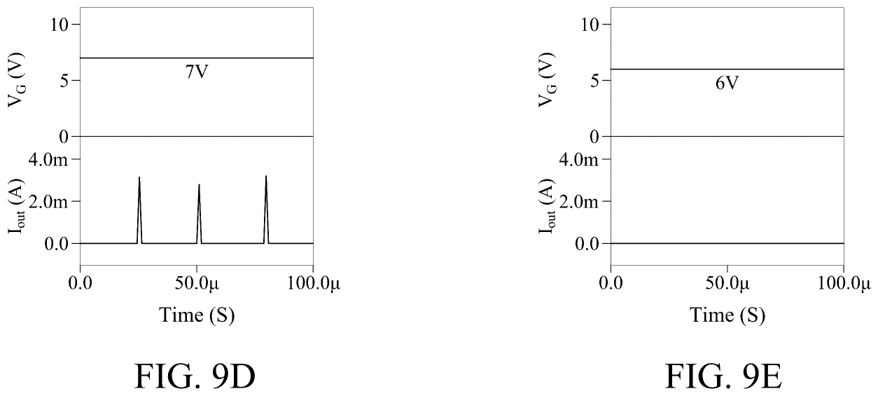

FIG. 9A to FIG. 9E are I-t graphs of spike signal encoding at a variable voltage. As shown in FIG. 9A to FIG. 9E, and referring to FIG. 7 and FIG. 8, for different gate voltages V_{G} applied, different current signals may be modulated into spike patterns, and then, different spike patterns may be encoded so as to achieve the operation mode similar to that of neurons and synapses, which conforms to the information transmission mode of spike neural network (SNN).

Based on the above, the light sensing and memory integrated electronic device 1 provides a single device, which can perform effects of light sensing and volatile memory and can convert a current signal into a spike form through modulation of applied voltage so as to perform encoding and discrimination. On the premise of reducing circuit elements, the light sensing and memory integrated electronic device can simplify the circuit and effectively reduce the photoelectric signal conversion time, and it can also make it more lightweight and improve space utilization efficiency, and achieve higher computing power.

Although the present disclosure has been described in considerable detail with reference to certain preferred embodiments thereof, the disclosure is not for limiting the scope of the invention. Persons having ordinary skill in the art may make various modifications and changes without departing from the scope and spirit of the disclosure. Therefore, the scope of the appended claims should not be limited to the description of the preferred embodiments described above.

What is claimed is:

1. A light sensing and memory integrated electronic device, comprising:
a thin film transistor element, comprising a channel layer, a source layer and a drain layer, wherein the channel layer is made of a transparent oxide, and the source layer and the drain layer are on the channel layer separately from each other; and
a memory element, on the source layer, and comprising a lower metal layer, a dielectric layer, a matching metal layer and an upper metal layer stacked in sequence from bottom to top, wherein the lower metal layer is connected to the source layer.

2. The light sensing and memory integrated electronic device according to claim 1, wherein the transparent oxide is selected from a group consisting of zinc oxide, indium oxide, gallium oxide, zinc tin oxide, indium zinc oxide (IZO), indium gallium oxide and indium gallium zinc oxide (IGZO).

3. The light sensing and memory integrated electronic device according to claim 1, wherein the source layer and the drain layer are made of aluminum.

4. The light sensing and memory integrated electronic device according to claim 1, wherein the drain layer comprises an aluminum layer and a platinum layer, the aluminum layer is in contact with the channel layer, and the platinum layer is stacked on the aluminum layer.

5. The light sensing and memory integrated electronic device according to claim 1, wherein the lower metal layer and the upper metal layer are made of platinum.

6. The light sensing and memory integrated electronic device according to claim 1, wherein the dielectric layer is selected from a group consisting of aluminum oxide, tantalum oxide, zirconium oxide, hafnium oxide, titanium oxide, tungsten oxide and niobium oxide.

7. The light sensing and memory integrated electronic device according to claim 6, wherein the matching metal layer is made of vanadium (V).

8. The light sensing and memory integrated electronic device according to claim 1, wherein a thickness of the channel layer is about 1/12 to 1/10 of a thickness of the source layer and the drain layer.

9. The light sensing and memory integrated electronic device according to claim 8, wherein a thickness of the upper metal layer is ⅔ to ¾ of a thickness of the lower metal layer, a thickness of the dielectric layer is ⅖ to ⅗ of the thickness of the lower metal layer, a thickness of the matching metal layer is 9/8 to 5/4 of the thickness of the lower metal layer, and the thickness of the lower metal layer is ⅖ to ⅗ of the thickness of the source layer and the drain layer.

10. The light sensing and memory integrated electronic device according to claim 1, further comprising a base, wherein the thin film transistor element is on the base, the base comprises a P-doped silicon substrate and a silicon dioxide layer, and the silicon dioxide layer is between the P-doped silicon substrate and the channel layer.
